(19) United States
(12) Patent Application Publication
(10) Pub. No.: US 2015/0170980 A1
(43) Pub. Date: Jun. 18, 2015

(54) SEMICONDUCTOR DEVICE

(71) Applicant: KABUSHIKI KAISHA TOSHIBA, Minato-ku (JP)

(72) Inventors: Yoshiyuki Kosaka, Yokohama (JP); Takashi Yamazaki, Yokohama (JP)

(73) Assignee: KABUSHIKI KAISHA TOSHIBA, Minato-ku (JP)

(21) Appl. No.: 14/482,438

(22) Filed: Sep. 10, 2014

(30) Foreign Application Priority Data
Dec. 13, 2013 (JP) 2013-258703

(51) Int. Cl. H01L 21/66; H01L 23/60; H01L 23/498

(52) U.S. Cl. CPC H01L 22/30; H01L 23/49827; H01L 23/60

(57) ABSTRACT

A semiconductor device of embodiment includes: a wiring substrate having a first surface, a second surface and a side surface; a semiconductor element mounted on the first surface; a sealing resin layer sealing the semiconductor element and the first surface; a conductive shield layer covering the sealing resin layer and the side surface; and plural vias. At least one via is electrically connected to the conductive shield layer, and the plural vias are each arranged along peripheral part of the wiring substrate. When plural predetermined vias arranged at one side part of the peripheral part of the wiring substrate are seen through thickness direction of the wiring substrate, width of area totally occupied by the plural predetermined vias in direction perpendicular to the side part is larger than width an area occupied by each of the predetermined vias as a single via in direction along the side part.

### CROSS-REFERENCE TO RELATED APPLICATION

This application is based upon and claims the benefit of priority from Japanese Patent Application No. 2013-258703, filed on Dec. 13, 2013; the entire contents of which are incorporated herein by reference.

### FIELD

Embodiments described herein relate generally to a semiconductor device.

### BACKGROUND

A semiconductor device having a function to suppress leakage of noise from inside is known. In this kind of semiconductor device, for example, a structure in which a periphery of a semiconductor device main body is covered with a metallic shield layer, and further, a ground wiring of a wiring substrate where a semiconductor element is mounted and the shield layer are connected, and so on are applied.

Here, a good shielding effect can be expected by reducing a connection resistance under a state in which the ground wiring of the wiring substrate and the shield layer are connected.

### BRIEF DESCRIPTION OF THE DRAWINGS

FIG. 1 is a side view illustrating a semiconductor device according to a first embodiment.

FIG. 2 is a sectional view of the semiconductor device illustrated in FIG. 1.

FIG. 3 is a sectional view illustrating a state before a conductive shield layer is formed at the semiconductor device in FIG. 1.

FIG. 4 is a plan view schematically illustrating a wiring substrate included by the semiconductor device in FIG. 1.

FIG. 5 is a sectional view illustrating the wiring substrate in FIG. 4.

FIG. 6 is a flowchart illustrating a major manufacturing process of the semiconductor device illustrated in FIG. 1.

FIG. 7A is a sectional view to explain the manufacturing process corresponding to steps S1, S2 in FIG. 6. FIG. 7B is a sectional view to explain the manufacturing process corresponding to step S3 in FIG. 6. FIG. 7C is a sectional view to explain the manufacturing process corresponding to step S4 in FIG. 6.

FIG. 8 is a plan view schematically illustrating a state before the wiring substrate in FIG. 4 is divided from a waste substrate.

FIG. 9 is a plan view illustrating a constitution of a via provided at side surfaces of the wiring substrate in FIG. 4.

FIG. 10 is a plan view illustrating a layout of the vias provided at the side surface of the wiring substrate in FIG. 4.

FIG. 11 is an A-A sectional view of FIG. 10.

FIG. 12 is a B-B sectional view of FIG. 10.

FIG. 13 is a plan view illustrating a layout of vias of a comparative example.

FIG. 14 is a C-C sectional view of FIG. 13.

FIG. 15 is a D-D sectional view of FIG. 13.

FIG. 16 is a plan view illustrating a constitution of vias disposed at a side surface of a wiring substrate included by a semiconductor device according to a second embodiment.

FIG. 17 is a plan view illustrating a constitution of vias disposed at a side surface of a wiring substrate included by a semiconductor device according to a third embodiment.

FIG. 18 is a sectional view illustrating a constitution of the via in FIG. 17.

FIG. 19 is a sectional view schematically illustrating a semiconductor device according to another embodiment whose structure is different from the first to third embodiments.

FIG. 20 is a view schematically illustrating another wiring substrate whose structure is different from the wiring substrate in FIG. 4.

FIG. 21A is a plan view schematically illustrating a semiconductor device according to still another embodiment whose structure is different from the semiconductor devices according to the first to third embodiments and the semiconductor device illustrated in FIG. 19. FIG. 21B is an E-E sectional view of FIG. 21A.

FIG. 22 is a sectional view schematically illustrating a semiconductor device according to yet another embodiment whose structure is different from the semiconductor devices according to the first to third embodiments and the semiconductor devices illustrated in FIG. 19 and FIG. 21B.

### DETAILED DESCRIPTION

In one embodiment, a semiconductor device includes: a wiring substrate; a semiconductor element; a sealing resin layer; a conductive shield layer; and plural vias. The wiring substrate has a first surface, a second surface and a side surface. The semiconductor element is mounted on the first surface. The sealing resin layer seals the semiconductor element and the first surface. The conductive shield layer covers the sealing resin layer and the side surface. Among the plural vias, at least one via is electrically connected to the conductive shield layer, and the plural vias are each arranged along a peripheral part of the wiring substrate. Further, when plural predetermined vias arranged at one side part of the peripheral part of the wiring substrate from among the plural vias are seen through a thickness direction of the wiring substrate, a width of an area totally occupied by the plural predetermined vias in a direction perpendicular to the side part is larger than a width of an area occupied by each of the predetermined vias as a single via in a direction along the side part.

Hereinafter, embodiments are described based on the drawings.

### First Embodiment

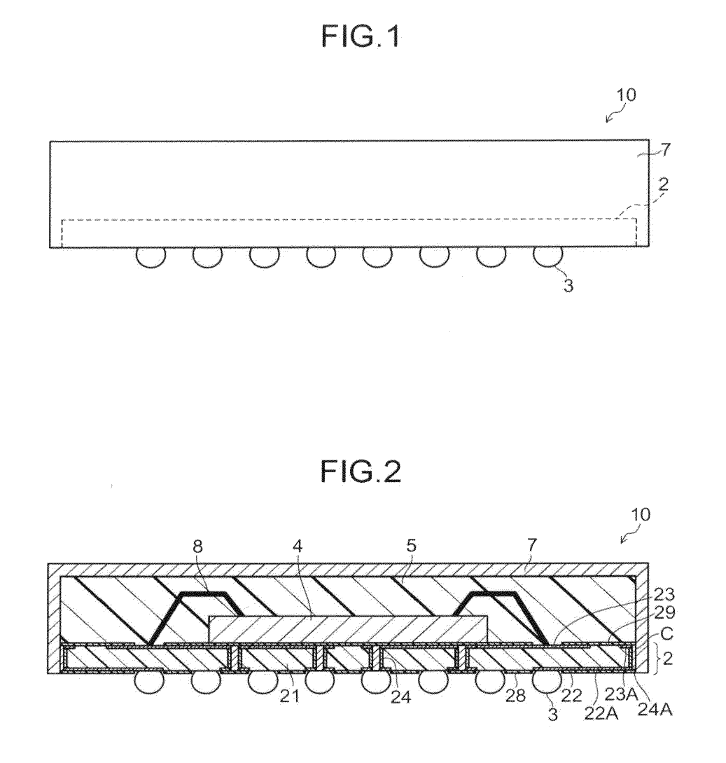

As illustrated in FIG. 1 to FIG. 3, a semiconductor device 10 according to the present embodiment is a semiconductor package having a EMI (electromagnetic interference) shielding function in which a conductive shield layer 7 is formed for an FBGA (Fine pitch Ball Grid Array) 6. The FBGA 6 mainly includes, for example, a wiring substrate 2 being an interposer board and so on, solder balls 3, a semiconductor element (semiconductor chip) 4, and a sealing resin layer (molding resin layer) 5. As illustrated in FIG. 1 to FIG. 3, the wiring substrate has a first surface, a second surface and side surfaces.

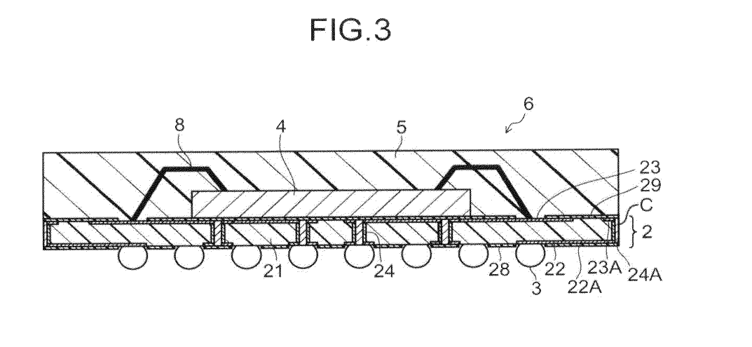

The semiconductor element 4 is mounted on the first surface of the wiring substrate 2. The solder balls 3 are external connection terminals provided at the second surface (a non-mounting surface of the semiconductor element) side of the wiring substrate 2. As illustrated in FIG. 2 and FIG. 3, the sealing resin layer 5 seals the semiconductor element 4 and the first surface of the wiring substrate 2. As illustrated in FIG. 2, the conductive shield layer 7 covers the sealing resin layer 5 and the side surfaces of the wiring substrate 2. In the wiring substrate 2, two layers of wiring layers are formed at a substrate 21 having an electrical insulating property. Namely, a first wiring layer 23 is provided at the first surface (an upper surface in FIG. 2) of the wiring substrate 2. Besides, a second wiring layer 22 is provided at the second surface (a lower surface in FIG. 2) of the wiring substrate 2.

The first and second wiring layers 23, 22 may be each made up from two layers or more of a conductive layer without being limited to a conductive layer in a single layer structure. Namely, the wiring substrate 2 may be a multilayer board of, for example, three layers or more. Besides, the wiring substrate 2 includes vias 24, 24A enabling an interlayer connection between the first wiring layer 23 and the second wiring layer 22. Nickel plating, gold plating, and so on are performed on surfaces of the first and second wiring layers 23, 22, and vias 24, 24A according to need by using a copper foil and a conductive paste containing silver or copper.

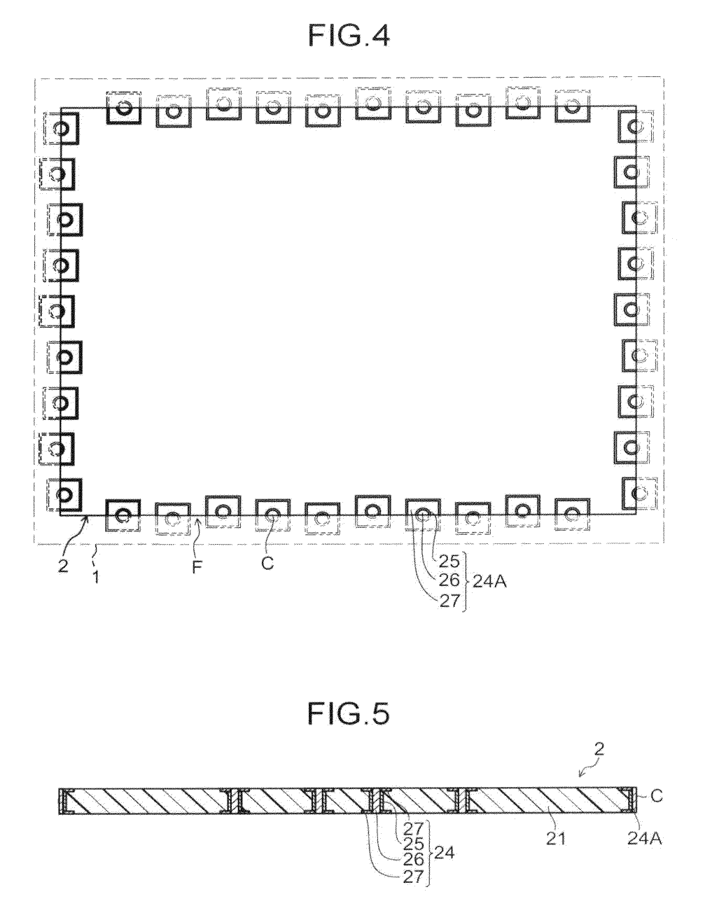

FIG. 4 is a plan view schematically illustrating the wiring substrate 2. Note that in FIG. 4, a waste substrate (a non-product part) 1 which is divided from the wiring substrate 2 by dicing and so on is illustrated by a two-dot chain line (imaginary line). As illustrated in FIG. 4 and FIG. 5, each of the vias 24, 24A includes a conductive layer 25, a land 27, and a padding material 26. The conductive layer 25 is formed at an inner wall surface of a through hole penetrating the wiring substrate 2. The land 27 electrically connects the conductive layer 25 and the first and second wiring layers 23, 22.

The padding material 26 is filled in a hollow part inside the conductive layer 25. The padding material 26 is made up of, for example, a conductive resin and so on. The padding material 26 is preferably formed by a material excellent in adhesiveness with the conductive shield layer 7. The conductive material is applied for the padding material 26, and thereby, an electrical connection area with the conductive shield layer 7 increases, and lowering of a connection resistance value between the via 24A and the conductive shield layer 7 can be expected. Besides, the vias 24, 24A may be ones in which a metal material such as copper is filled in the through hole by, for example, the plating process. Note that the padding material 26 applied for the via 24 may be made up of an insulating resin.

The solder balls 3 provided at the second surface side of the wiring substrate 2 are electrically connected to the second wiring layer 22. Besides, the first wiring layer 23 including a signal wiring, a ground wiring, and so on is formed at the first surface side of the wiring substrate 2. Further, the wiring substrate 2 includes solder resist layers 29, 28 respectively formed at the first and second surface sides.

The semiconductor element 4 includes an electrode pad (not-illustrated) at an upper surface thereof. The electrode pad of the semiconductor element 4 is electrically connected to the first wiring layer 23 of the wiring substrate 2 via bonding wires 8 made of, for example, gold, silver, copper, and so on. The sealing resin layer 5 seals the semiconductor element 4 together with the bonding wires 8.

The conductive shield layer 7 is preferably formed by a metal layer whose resistivity is low so as to suppress leakage of unnecessary electromagnetic waves (noises) radiated from the semiconductor element 4 in the sealing resin layer 5 and the wiring layers 22, 23 of the wiring substrate 2, and for example, the metal layer using copper, silver, nickel, and so on is applied. A thickness of the conductive shield layer 7 is preferably set based on the resistivity thereof. Note that it is desirable to set the thickness of the conductive shield layer 7 such that a sheet resistance value in which the resistivity is divided by the thickness of the conductive shield layer 7 becomes, for example, 0.5Ω or less.

The unnecessary electromagnetic waves radiated from the semiconductor element 4 and so on are shielded by the conductive shield layer 7 covering the sealing resin layer 5, and therefore, the leakage toward outside is suppressed. There is a possibility in which the unnecessary electromagnetic waves leak from the side surfaces of the wiring substrate 2. Accordingly, the plural vias 24A exposing to each side face (each end surface) of the rectangular wiring substrate 2 are disposed at the semiconductor device 10 as illustrated in FIG. 2 to FIG. 5. The vias 24A are connected to ground wirings 22A, 23A making up a part of the wiring layers 22, 23. The via 24A includes a cut surface C which is cut (divided) relative to the waste substrate 1, and is disposed such that the cut surface C is exposed to the side surface of the wiring substrate 2.

The ground wirings 22A, 23A are disposed at the side surfaces (an inner side of the wiring substrate 2 than the via 24A) of the wiring substrate 2 so as to be connected to the via 24A. The conductive shield layer 7 is electrically connected to the cut surface C of the via 24A. The conductive shield layer 7 and the via 24A are connected via the cut surface C of the via 24A, and therefore, a connection state between both becomes close, and it becomes possible to lower the connection resistance.

The cut surface C of the via 24A preferably includes a cut surface of the conductive layer 25 and a cut surface of the conductive padding material 26. A connection area between the conductive shield layer 7 and the cut surface C of the via 24A is increased, and thereby, it is possible to connect the conductive shield layer 7 and the via 24A in a more close contact state.

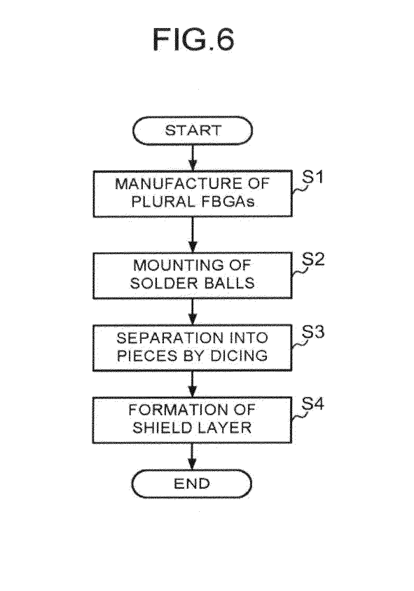

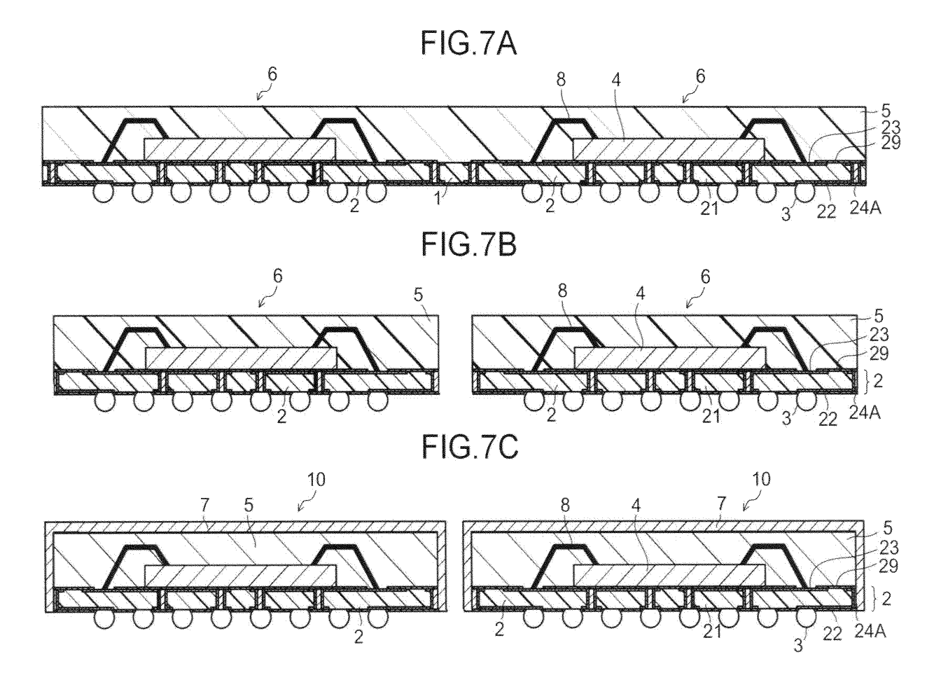

The semiconductor device 10 as stated above is, for example, manufactured as described below. At first, as illustrated in FIG. 6 and FIG. 7A, the plural FBGAs 6 which are collectively sealed by the sealing resin layer 5 are manufactured (S1). Next, the solder balls 3 are collectively mounted on the second surface side of the wiring substrate 2 (S2). Subsequently, as illustrated in FIG. 6 and FIG. 7B, the division from the waste substrate 1 is performed by dicing to separate the FBGAs 6 into pieces (S3). The dicing is performed to cut the vias 24A disposed at the side surfaces of the wiring substrate 2 along a thickness direction of the wiring substrate 2. The cut surface C of the via 24A is formed by the dicing.

Next, as illustrated in FIG. 6 and FIG. 7C, the conductive shield layer 7 is formed to cover each of the separated FBGAs 6 (S4). The conductive shield layer 7 is formed by coating the conductive paste by, for example, the transfer method, the screen printing method, the spray coating method, the jet dispensing method, the ink jet method, the aerosol method, and so on. As the conductive paste, one containing, for example, silver and/or copper and a resin as major constituents, and whose resistivity is low is desirable.

Besides, the conductive shield layer 7 may be formed by applying a deposition method depositing copper, nickel, and so on by the electroless plating method or the electrolytic plating method, a deposition method depositing a two-layer film of copper and stainless by, for example, performing preprocessing (etching of a surface) by the reverse sputtering method, and thereafter, the normal sputtering method, and so on. The conductive shield layer 7 as stated above is formed to cover the sealing resin layer 5 and the side surfaces (the end faces) of the wiring substrate 2.

Further, a protective layer excellent in a corrosion resistance and a migration resistance may be formed to cover the conductive shield layer 7 according to need. For example, a polyimide resin and so on are used as a material of the protective layer. Finally, the conductive shield layer 7 (and the protective layer and so on) is baked to be cured, and thereby, the semiconductor device 10 is manufactured. Note that the semiconductor device 10 is printed thereon according to need. The printing is performed by the printing by a laser, the transfer method, and so on.

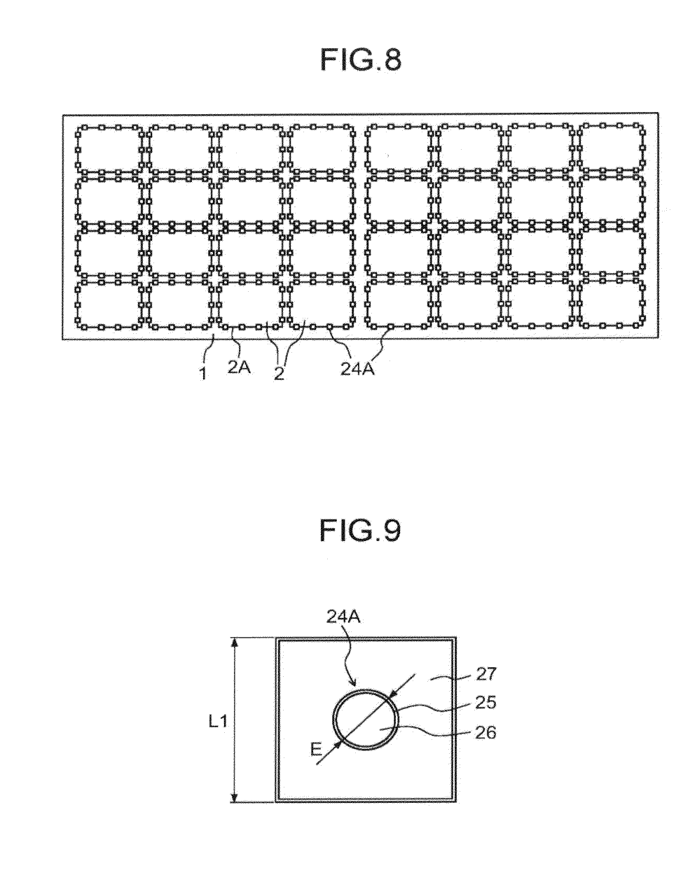

Next, a characteristic constitution of the above-stated plural vias 24A (vias 24B, 24C, 24D, 24E) of the semiconductor device 10 according to the present embodiment is described in detail based on FIG. 8 to FIG. 15. During a manufacturing process of the semiconductor device 10, as illustrated in FIG. 8, plural (32 pieces in the example in FIG. 8) wiring substrates 2 and the waste substrate (non-production part) 1 are integrally formed. The wiring substrates 2 are divided from the waste substrate 1 at the dicing process.

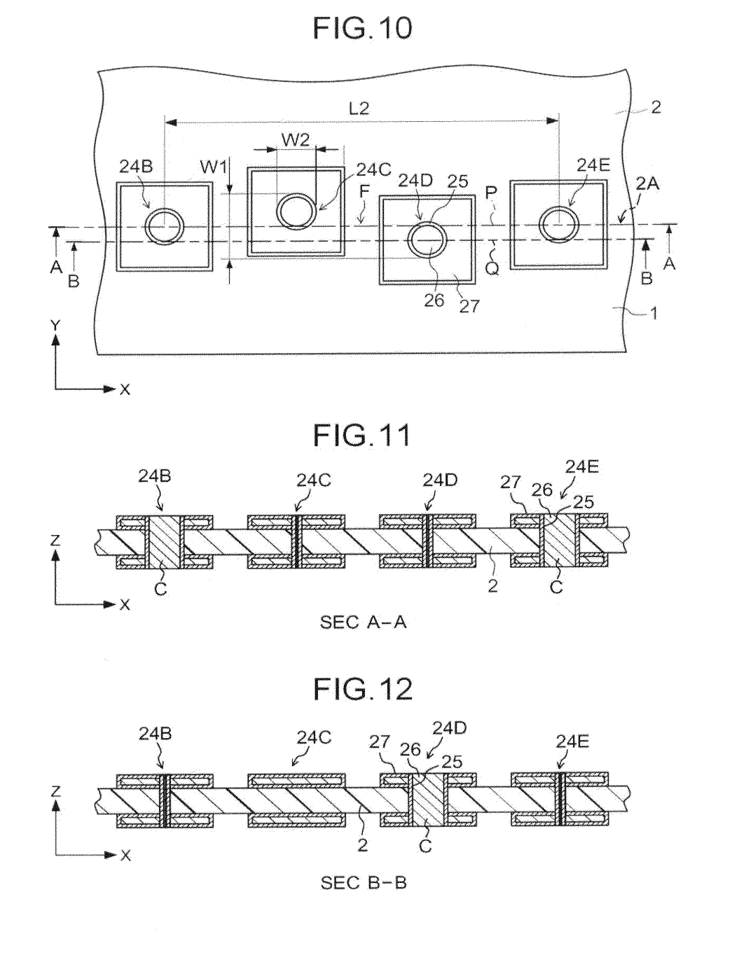

As illustrated in FIG. 8 and FIG. 10, at least one of (at least any of) the plural vias 24A before the division (the vias 24B, 24C, 24D, 24E in FIG. 10) is electrically connected to the conductive shield layer 7, and they are each arranged along a peripheral part (a boundary part between the waste substrate 1 and the wiring substrate 2) F of the wiring substrate 2. As illustrated in FIG. 9, the via 24A is formed to have, for example, a diameter E of 75 μm. The square land 27 is formed to have one side L1 of, for example, 230 μm.

Here, as illustrated in FIG. 10 to FIG. 12, when the plural predetermined vias 24B, 24C, 24D, 24E arranged at one side part 2A of the peripheral part of the wiring substrate 2 (arranged at the boundary part F between the waste substrate 1 and the one side part 2A of the wiring substrate 2) from among the plural vias 24A are seen through a thickness direction (a Z direction in each of FIG. 11 and FIG. 12) of the wiring substrate 2, a width W1 of an area totally occupied by the plural predetermined vias 24B, 24C, 24D, 24E in a direction perpendicular to the side part 2A (a Y direction in FIG. 10) is constituted to be larger than a width W2 of an area occupied by each of the predetermined vias 24B, 24C, 24D, 24E as a single via in a direction along the side part 2A (an X direction in FIG. 10).

Namely, as illustrated in FIG. 10, when the plural predetermined vias 24B, 24C, 24D, 24E are seen through the thickness direction of the wiring substrate 2, at least one of the plural predetermined vias 24B, 24C, 24D, 24E is intentionally disposed while being shifted (offset) in the direction perpendicular to the side part 2A (the Y direction in FIG. 10) relative to the other predetermined vias. Besides, the plural predetermined vias 24B, 24C, 24D, 24E (the via 24A) are each connected to the ground wirings 22A, 23A as illustrated in FIG. 2. Besides, at least one of the plural predetermined vias 24B, 24C, 24D, 24E is exposed to the side surface of the wiring substrate 2, and is electrically connected to the conductive shield layer 7 via the exposed side surface.

In detail, as illustrated in FIG. 10, the vias 24B, 24E are disposed such that centers of vias 24B, 24E main bodies overlap with an ideal outline process position (a shift amount from a design value is 0 um) P as is a design value in the direction perpendicular to the side part 2A (the Y direction in FIG. 10). Besides, the via 24C is disposed at a position in which a center of a via 24C main body is shifted in a first direction (an upper direction in FIG. 10) for a radial extent (for example 37.5 um) in the direction perpendicular to the side part 2A. Further, the via 24D is disposed at an outline process position Q in which a center of a via 24D main body is shifted in a second direction (a lower direction in FIG. 10) in reverse to the first direction for a radial extent (for example, 37.5 urn) in the direction perpendicular to the side part 2A.

At the wiring substrate 2 divided from the waste substrate 1 by the dicing, any one of the cut surfaces C (side surfaces) of the vias from among the predetermined vias 24B, 24C, 24D, 24E is thereby exposed as illustrated in FIG. 11, FIG. 12 even when an actual outline process position shifts in the first or second direction for the radial extent of the via main body. Accordingly, a desired connection area between the conductive shield layer 7 and the cut surface C of the via is secured. It is thereby possible to set a variation of a resistance value of the conductive shield layer 7 connected to the ground wiring within a design-allowable range, and to obtain a desired shielding effect.

In the semiconductor device 10 according to the present embodiment as exemplified in FIG. 10, three patterns of vias of the via 24B (or the via 24E) which is disposed at the position as is the design value, the via 24C which is shifted in the first direction, and the via 24D which is shifted in the second direction are set to be one cycle, and the three patterns of vias are repeatedly disposed in this cycle along the boundary part F (the side part of the wiring substrate 2) with a pitch L2 (for example, a pitch of 1000 μm). The above-stated shift amount of the via is determined in consideration of variety of an outline process accuracy of the wiring substrate 2 by the dicing.

Here, the amounts to be shifted in the first and second directions each may be set to be two stages. Namely, five patterns of vias of a via shifted for a first amount and a via shifted for a second amount in the first direction, a via shifted for a first amount and a via shifted for a second amount in the second direction, and the via disposed at the position as is the design value are set to be one cycle, and the five patterns of vias may be repeatedly disposed in this cycle. Besides, seven patterns or more of a lot of vias in which the shift amount is further segmentized may be repeatedly disposed.

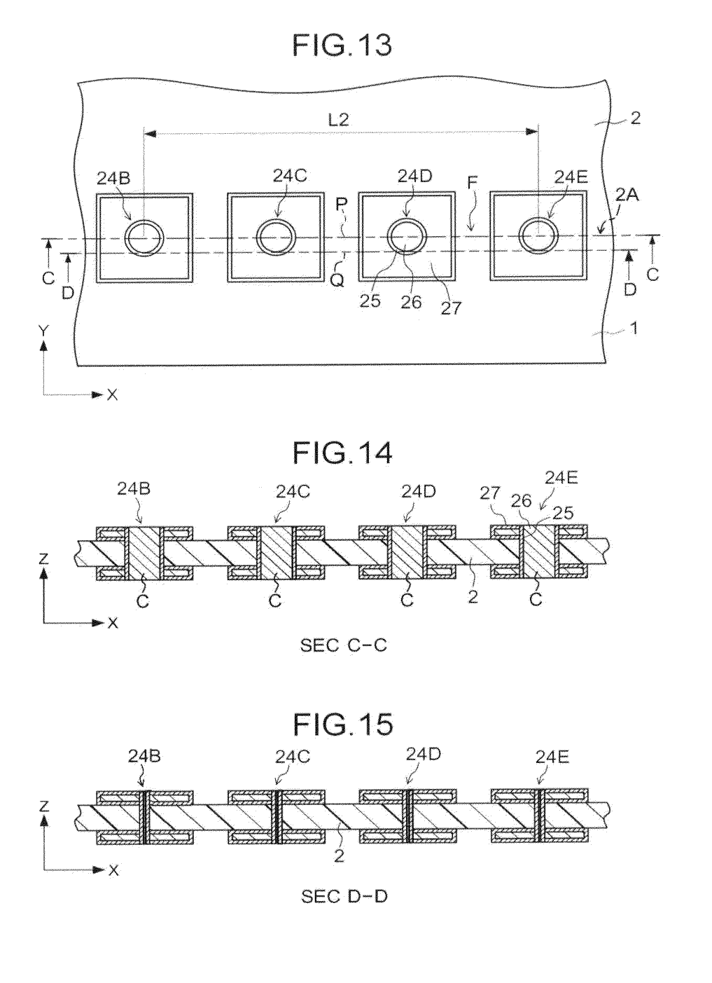

On the other hand, in a semiconductor device of a comparative example, all of the predetermined vias 24B, 24C, 24D, 24E are linearly arranged along the boundary part F (the side part of the wiring substrate 2) as illustrated in FIG. 13 to FIG. 15. In this case, the outline process accuracy of the wiring substrate 2 by the dicing is, for example, ±50 urn, and when the wiring substrate 2 is actually divided at the outline process position Q which shifts for, for example, 37.5 um from the outline process position P as is the design value, any of the cut surfaces C of the vias 24B, 24C, 24D, 24E is seldom exposed as illustrated in FIG. 15. Besides, actually, it is necessary to consider variation of an accuracy of a via diameter in addition to the variation of the outline process accuracy of the wiring substrate 2. Accordingly, in the semiconductor device of the comparative example, a connection resistance between the conductive shield layer and the via becomes large, and there is fear that the shielding effect is lowered.

On the other hand, in the semiconductor device 10 according to the embodiment, the vias 24B, 24E are disposed at the outline process position P as is the design value, and the via 24C is shifted in the first direction (the upper direction in FIG. 10), further the via 24D is shifted in the second direction (the lower direction in FIG. 10) to set at the outline process position Q as illustrated in FIG. 10, and thereby, it is possible to largely expose any of the cut surfaces C of the vias as illustrated in FIG. 11 and FIG. 12 even when the actual outline process position of the wiring substrate 2 by the dicing shifts in the first or second direction from the outline process position P as is the design value. Therefore, according to the semiconductor device 10 of the present embodiment, the connection between the conductive shield layer 7 and the via becomes closer to thereby suppress the variation of the connection resistance, and thereby it is possible to secure the desired shielding effect by the conductive shield layer 7.

### Second Embodiment

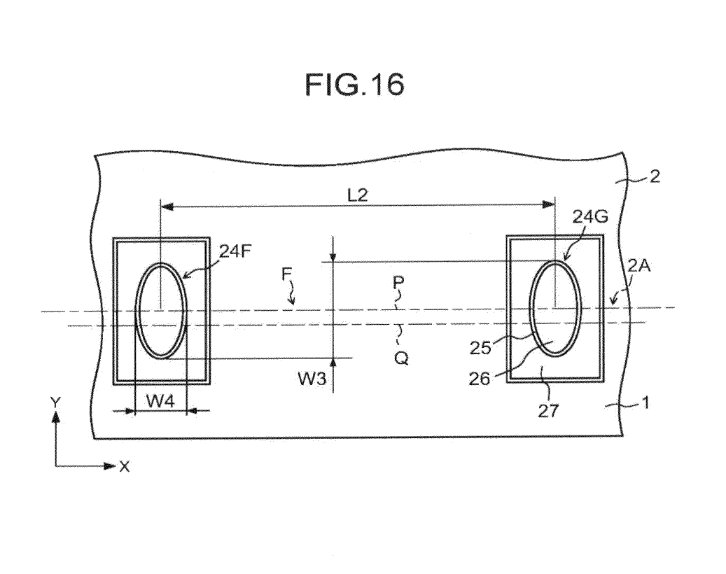

Next, a second embodiment is described based on FIG. 16. Note that in FIG. 16, the same reference numerals and symbols are used to designate the same components as the components in the first embodiment illustrated in FIG. 10, and the redundant description thereof will not be given.

A semiconductor device according to the second embodiment includes predetermined vias 24F, 24G as illustrated in FIG. 16 instead of the predetermined vias 24B, 24C, 24D, 24E as illustrated in FIG. 10 included by the semiconductor device 10 according to the first embodiment. As illustrated in FIG. 16, when the plural predetermined vias 24F, 24G arranged at the one side part 2A (the boundary part F between the waste substrate 1 and the one side part 2A of the wiring substrate 2) at the peripheral part of the wiring substrate 2 from among the plural vias provided at the semiconductor device of the present embodiment are seen through the thickness direction of the wiring substrate 2, a width W3 of an area totally occupied by the plural predetermined vias 24F, 24G in a direction perpendicular to the side part 2A (a Y direction in FIG. 16) is constituted to be larger than a width W4 of an area occupied by each of the predetermined vias 24F, 24G as a single via in a direction along the side part 2A (an X direction in FIG. 16).

Namely, in the semiconductor device according to the second embodiment, when the vias 24F, 24G is seen from the thickness direction (a plane direction) of the wiring substrate 2, an aspect ratio of a shape of each of the vias 24F, 24G is different. Specifically, the vias 24F, 24G are formed to be elliptical shapes. Each of the elliptical vias 24F, 24G is disposed to direct a major axis thereof toward the direction perpendicular to the side part 2A of the wiring substrate 2 (the Y direction in FIG. 16). The elliptical vias 24F, 24G enable to be molded by the laser processing or the photolithography processing.

According to the semiconductor device of the second embodiment, it is possible to absorb the variation of the outline process position (the cut position of vias) of the wiring substrate 2 by the dicing by the elliptical shapes of the vias 24F, 24G, and therefore, it is possible to suppress the variation of a connection resistance between the conductive shield layer 7 and the vias 24F, 24G, and to obtain the desired shielding effect.

Note that the major axes of the elliptical vias 24F, 24G as stated above may be disposed to incline relative to the direction perpendicular to the side part 2A of the wiring substrate 2 (the Y direction in FIG. 16). In this case, it is possible to increase areas of cut surfaces of the vias 24F, 24G, and therefore, a good shielding effect by the conductive shield layer 7 which is connected to the cut surfaces of the vias 24F, 24G can be expected. Besides, at least one of the elliptical vias 24F, 24G may be disposed while being shifted in a first direction (an upper direction in FIG. 16) perpendicular to the side part 2A or a second direction (a lower direction in FIG. 16) which is different from the first direction as exemplified in FIG. 10.

### Third Embodiment

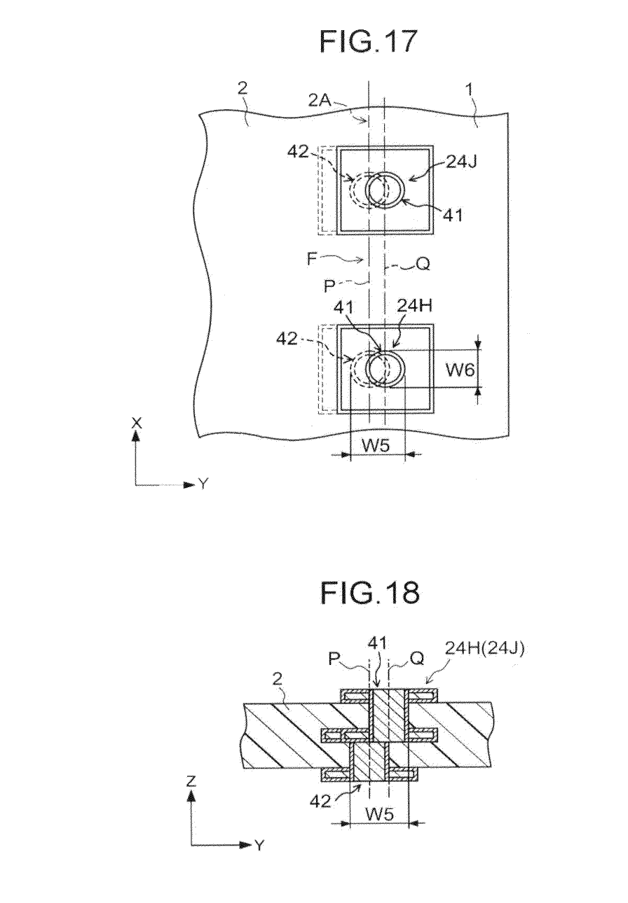

Next, a third embodiment is described based on FIG. 17 and FIG. 18. Note that in FIG. 17 and FIG. 18, the same reference numerals and symbols are used to designate the same components as the components in the first embodiment illustrated in FIG. 10, and the redundant description thereof will not be given.

A semiconductor device according to the third embodiment includes predetermined vias 24H, 24J as illustrated in FIG. 17 and FIG. 18 instead of the predetermined vias 24B, 24C, 24D, 24E illustrated in FIG. 10 included by the semiconductor device 10 according to the first embodiment. As illustrated in FIG. 17, when the plural predetermined vias 24H, 24J arranged at the one side part 2A (the boundary part F between the waste substrate 1 and the one side part 2A of the wiring substrate 2) at the peripheral part of the wiring substrate 2 from among the plural vias provided at the semiconductor device of the present embodiment are seen through the thickness direction (a Z direction in FIG. 18) of the wiring substrate 2, a width W5 of an area totally occupied by the plural predetermined vias 24H, 24J in a direction perpendicular to the side part 2A (a Y direction in FIG. 17) is constituted to be larger than a width W6 of an area occupied by each of the predetermined vias 24H, 24J as a single via in a direction along the side part 2A (an X direction in FIG. 17).

Here, the wiring substrate 2 of the semiconductor device according to the present embodiment is a multilayer board in a three-layer structure. Besides, each of the plural predetermined vias 24H, 24J is constituted by a stacked via. Namely, in the semiconductor device of the third embodiment, when the plural predetermined vias 24H, 24J are seen through a direction along the first surface of the wiring substrate 2 (the X direction in FIG. 17), a portion (a via element connecting between a first layer and a second layer from an upper surface) 41 formed at the first surface (an upper surface in FIG. 18) side of the wiring substrate 2 by each of the predetermined vias 24H, 24J and a portion (a via element connecting between the second layer and a third layer from the upper surface) 42 formed at the second surface (a lower surface in FIG. 18) side of the wiring substrate 2 by each of the predetermined vias 24H, 24J are disposed while being relatively shifted in the direction (the Y directions in FIG. 17 and FIG. 18) perpendicular to the side part 2A of the wiring substrate 2.

According to the semiconductor device of the third embodiment, as illustrated in FIG. 17 and FIG. 18, it is possible to absorb the variation of the outline process position (the cut position of the vias) of the wiring substrate 2 by the dicing by the above-stated structure of the vias (the stacked vias) 2411, 24J, and therefore, it is possible to suppress the variation of a connection resistance between the conductive shield layer 7 and the vias 24H, 24J, and to secure the desired shielding effect. Note that in FIG. 18, the wiring substrate 2 in the three-layer structure is exemplified, but the similar shielding effect can be obtained when a wiring substrate having a multilayer structure of four layers or more is applied.

Note that the example in which the portion (the via element) 41 of the vias (the stacked vias) 24H, 24J is shifted in a first direction (a right direction in FIG. 18) from the outline process position (the cut position of the vias) P as it is designed is illustrated, but instead of the above, a structure in which the portion (the via element) 41 of the vias 24H, 24J is shifted in a second direction (a left direction in FIG. 18) may be applied. Besides, at least one of the vias (the stacked vias) 24H, 24J illustrated in FIG. 17, FIG. 18 may be disposed while being shifted in a first direction (a left direction in FIG. 17) perpendicular to the side part 2A or a second direction (a right direction in FIG. 17) which is different from the first direction as exemplified in FIG. 10. Further, the vias (the stacked vias) 24H, 24J as stated above may be formed to be elliptical shapes as the second embodiment.

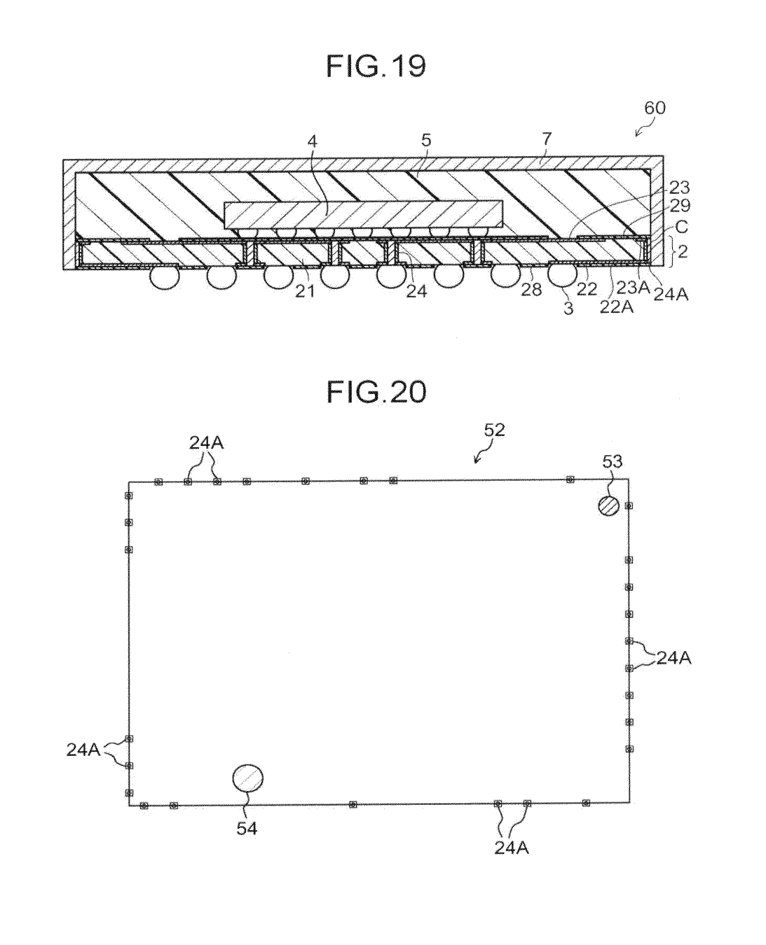

For example, in the above-stated embodiment, the example in which the semiconductor element 4 is connected to the wiring substrate 2 by the wire bonding is illustrated, but as illustrated in FIG. 19, it is possible to constitute a semiconductor device 60 in an embodiment in which the semiconductor element 4 is flip-chip connected to the wiring substrate 2.

Besides, for example, FIG. 20 is a schematic view in which a wiring substrate 52 whose wiring pattern structure including the vias 24A is partly different from the wiring substrate 2 exemplified in FIG. 4 is seen from the second surface (the non-mounting surface of the semiconductor element) side. The wiring substrate 52 includes at least one of the structure of the vias 24B, 24C, 24D, 24E of the first embodiment, the structure of the vias 24F, 24G of the second embodiment, and the structure of the vias 24H, 24J of the third embodiment exemplified in FIG. 10 to FIG. 12, and FIG. 16 to FIG. 18. As illustrated in FIG. 20, the plural vias 24A disposed at side surfaces of the wiring substrate 52 are laid out so as to correspond to each of positions of the plural wiring patterns wired on the wiring substrate 52. It is also possible to constitute the semiconductor device of the embodiment applying the wiring substrate 52 as stated above.

Besides, as stated above, the wiring substrate 52 applied to the semiconductor device includes a first pad 53 used for a resistance value measurement which is electrically connected to the conductive shield layer 7 at the non-mounting surface side of the semiconductor element 4 as illustrated in FIG. 20. Besides, the wiring substrate 52 includes a second pad 54 used for the resistance value measurement which is electrically connected to the conductive shield layer 7 at the non-mounting surface side of the semiconductor element 4. Further, the second pad 54 is also used as an index mark for alignment of the wiring substrate 52.

Namely, the semiconductor device including the wiring substrate 52 enables to perform an alignment (identification of a substrate orientation) of the wiring substrate 52 by using the second pad 54, and to measure the resistance value (the shielding effect) including the conductive shield layer 7 by bringing a pair of checker pins and so on for a shield test into contact with the first pad 53 and the second pad 54.

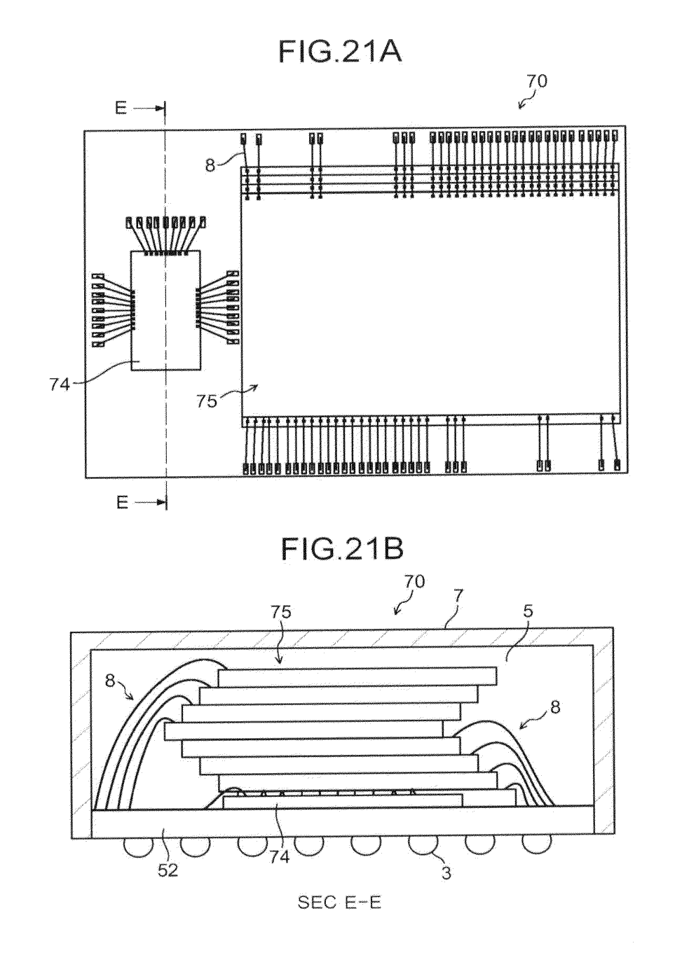

Further, FIG. 21 are views schematically illustrating a semiconductor device 70 of another embodiment whose constitution is partly different from the semiconductor device 10 exemplified in FIG. 2. FIG. 21A is a plan view schematically illustrating the semiconductor device 70, and FIG. 21B is a sectional view schematically illustrating an E-E cross section of FIG. 21A. Note that states are illustrated in which the sealing resin layer 5 and the conductive shield layer 7 are seen in FIG. 21A, and the sealing resin layer 5 is seen in FIG. 21B. This semiconductor device 70 further includes NAND type flash memory chips 75 and a controller chip 74 as semiconductor elements in addition to the wiring substrate 52 illustrated in FIG. 20 having the above-stated constitution (or the wiring substrate 2 of the first to third embodiments). The semiconductor device 70 mounts eight pieces of the flash memory chips 75 on the wiring substrate 52 in sequentially stacked state.

The controller chip 74 totally controls operations of each of the flash memory chips 75. In the semiconductor device 70 including a number of flash memory chips 75 in a stacked state, small-sizing is enabled in addition to large-sizing of a storage capacity. Note that in FIG. 21A and FIG. 21B, a constitution in which the eight pieces of flash memory chips 75 are stacked is exemplified, but a semiconductor device in which 16 pieces of, four pieces of, or two pieces of the flash memory chips 75 are stacked may be constituted.

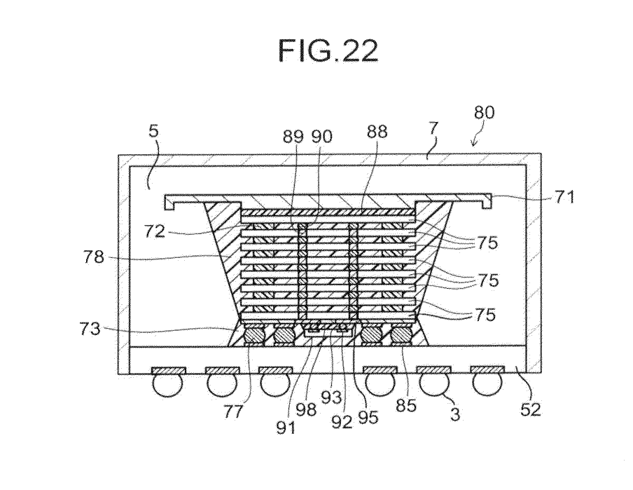

Besides, FIG. 22 is a sectional view illustrating a semiconductor device 80 according to still another embodiment whose constitution is different from the semiconductor devices 10, 60, 70 exemplified in FIG. 2, FIG. 19, and FIG. 21B. In the semiconductor device 80, a TSV (a Through-Silicon Via) 89 is applied as illustrated in FIG. 22 instead of the wire bonding connection of the semiconductor device 70, and enables an interlayer connection of the NAND type flash memory chips 75 and an I/F chip (interface) 91 as the semiconductor elements with the wiring substrate 52 (or the wiring substrate 2 of the first to third embodiments). The IF chip 91 includes an interface circuit to enable data communication between the flash memory chips 75 and external devices.

Besides, the semiconductor device 80 further includes a supporting substrate 71, an adhesive layer 88, a spacer 72, underfill resin layers 73, 78, 98, bump electrodes 77, 90, 93, an internal connection electrode 92, a rewiring layer 95, internal connection terminals 85, and so on as illustrated in FIG. 22. The above-stated TSV 89 electrically connects between each of the adjacent flash memory chips 75 via the bump electrodes 90. According to the semiconductor device 80 having the structure, it is possible to enable further small-sizing compared to the semiconductor device 70 illustrated in FIG. 21B in addition to enlarge the storage capacity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a wiring substrate having a first surface, a second surface and a side surface,
a semiconductor element mounted on the first surface;
a sealing resin layer sealing the semiconductor element and the first surface;
a conductive shield layer covering the sealing resin layer and the side surface; and
plural vias each arranged along a peripheral part of the wiring substrate, at least one of the vias being electrically connected to the conductive shield layer,
wherein when plural predetermined vias arranged at one side part of the peripheral part of the wiring substrate from among the plural vias are seen through a thickness direction of the wiring substrate, a width of an area totally occupied by the plural predetermined vias in a direction perpendicular to the side part is larger than a width of an area occupied by each of the predetermined vias as a single via in a direction along the side part.

2. The semiconductor device of claim 1,
wherein, when the plural predetermined vias are seen through the thickness direction of the wiring substrate, at least one of the plural predetermined vias is disposed while being shifted in a direction perpendicular to the side part relative to the other predetermined vias.

3. The semiconductor device of claim 1,
wherein, when the plural predetermined vias are seen through the thickness direction of the wiring substrate, an aspect ratio of a shape of each of the predetermined vias is different.

4. The semiconductor device of claim 2,
wherein, when the plural predetermined vias are seen through the thickness direction of the wiring substrate, an aspect ratio of a shape of each of the predetermined vias is different.

5. The semiconductor device of claim 1,
wherein, when the plural predetermined vias are seen through a direction along the first surface, a portion formed at the first surface side by each of the predetermined vias and a portion formed at the second surface side by each of the predetermined vias are disposed while being relatively shifted in the direction perpendicular to the side part.

6. The semiconductor device of claim 2,
wherein, when the plural predetermined vias are seen through a direction along the first surface, a portion formed at the first surface side by each of the predetermined vias and a portion formed at the second surface side by each of the predetermined vias are disposed while being relatively shifted in the direction perpendicular to the side part.

7. The semiconductor device of claim 3,
wherein, when the plural predetermined vias are seen through a direction along the first surface, a portion formed at the first surface side by each of the predetermined vias and a portion formed at the second surface side by each of the predetermined vias are disposed while being relatively shifted in the direction perpendicular to the side part.

8. The semiconductor device of claim 4,
wherein, when the plural predetermined vias are seen through a direction along the first surface, a portion formed at the first surface side by each of the predetermined vias and a portion formed at the second surface side by each of the predetermined vias are disposed while being relatively shifted in the direction perpendicular to the side part.

9. The semiconductor device of claim 5,
wherein, the wiring substrate is a multilayer board of three layers or more, and
each of the plural predetermined vias is a stacked via.

10. The semiconductor device of claim 6,
wherein the wiring substrate is a multilayer board of three layers or more, and each of the plural predetermined vias is a stacked via.

11. The semiconductor device of claim 7,
wherein the wiring substrate is a multilayer board of three layers or more, and each of the plural predetermined vias is a stacked via.

12. The semiconductor device of claim 8,
wherein the wiring substrate is a multilayer board of three layers or more, and each of the plural predetermined vias is a stacked via.

13. The semiconductor device of claim 1,
wherein the plural predetermined vias are each connected to ground wirings, and at least one of the plural predetermined vias is exposed to the side surface, and is electrically connected to the conductive shield layer via the exposed side surface.

14. The semiconductor device of claim 2,
wherein the plural predetermined vias are each connected to ground wirings, and at least one of the plural predetermined vias is exposed to the side surface, and is electrically connected to the conductive shield layer via the exposed side surface.

15. The semiconductor device of claim 3,
wherein the plural predetermined vias are each connected to ground wirings, and at least one of the plural predetermined vias is exposed to the side surface, and is electrically connected to the conductive shield layer via the exposed side surface.

16. The semiconductor device of claim 4,
wherein the plural predetermined vias are each connected to ground wirings, and at least one of the plural predetermined vias is exposed to the side surface, and is electrically connected to the conductive shield layer via the exposed side surface.

17. The semiconductor device of claim 1, further comprising:
a first pad used for a resistance value measurement provided at the second surface side, the first pad being electrically connected to the conductive shield layer; and
a second pad used for the resistance value measurement provided at the second surface side, the second pad constituting a mark for alignment of the wiring substrate, the second pad being electrically connected to the conductive shield layer.

18. The semiconductor device of claim 2, further comprising:
a first pad used for a resistance value measurement provided at the second surface side, the first pad being electrically connected to the conductive shield layer; and
a second pad used for the resistance value measurement provided at the second surface side, the second pad constituting a mark for alignment of the wiring substrate, the second pad being electrically connected to the conductive shield layer.

19. The semiconductor device of claim 3, further comprising:
a first pad used for a resistance value measurement provided at the second surface side, the first pad being electrically connected to the conductive shield layer; and
a second pad used for the resistance value measurement provided at the second surface side, the second pad constituting a mark for alignment of the wiring substrate, the second pad being electrically connected to the conductive shield layer.

20. The semiconductor device of claim 4, further comprising:
a first pad used for a resistance value measurement provided at the second surface side, the first pad being electrically connected to the conductive shield layer; and
a second pad used for the resistance value measurement provided at the second surface side, the second pad constituting a mark for alignment of the wiring substrate, the second pad being electrically connected to the conductive shield layer.
